(19) United States
(12) Patent Application Publication
(10) Pub. No.: US 2026/0019090 A1
(43) Pub. Date: Jan. 15, 2026

(54) CIRCUITRY AND METHOD

(71) Applicant: Arm Limited, Cambridge (GB)

(72) Inventor: David Hennah Mansell, Norwich (GB)

(73) Assignee: Arm Limited, Cambridge (GB)

(21) Appl. No.: 18/869,517

(22) PCT Filed: Apr. 27, 2023
(86) PCT No.: PCT/GB2023/051119

§ 371 Date: Nov. 26, 2024

(30) Foreign Application Priority Data
Jun. 1, 2022 (GB) 2208126.9

(51) Int. Cl. H03M 7/30; G06F 9/30

(52) U.S. Cl. CPC H03M 7/6005; G06F 9/3016

(57) ABSTRACT

Circuitry comprises instruction decoder circuitry to decode instructions for execution; processing circuitry to execute instructions decoded by the instruction decoder circuitry; interface circuitry defining an interface for data communication with data compression circuitry; in which the processing circuitry is responsive to one or more instructions of an instruction set defined for the processing circuitry to provide to the interface: input data to be processed by the data compression circuitry; and identification data identifying a compression system for use by the data compression circuitry to process the input data; and in which the processing circuitry is configured to receive from the interface: status data indicating whether data compression circuitry connected to the interface can process data using the compression system identified by the identification data; and, when the status data indicates that the data compression circuitry can process data using the compression system identified by the identification data, output data which has been processed from the input data by the data compression circuitry using the compression system identified by the identification data.

### BACKGROUND

This disclosure relates to data processing apparatus, methods and virtual machines.

Some data processing arrangements allow for processing operations such as neural processing to be performed using a set of processing values such as weight or activation values.

### SUMMARY

In an example arrangement there is provided circuitry comprising:
instruction decoder circuitry to decode instructions for execution;
processing circuitry to execute instructions decoded by the instruction decoder circuitry;
interface circuitry defining an interface for data communication with data compression circuitry;
in which the processing circuitry is responsive to one or more instructions of an instruction set defined for the processing circuitry to provide to the interface: input data to be processed by the data compression circuitry; and identification data identifying a compression system for use by the data compression circuitry to process the input data; and
in which the processing circuitry is configured to receive from the interface: status data indicating whether data compression circuitry connected to the interface can process data using the compression system identified by the identification data; and, when the status data indicates that the data compression circuitry can process data using the compression system identified by the identification data, output data which has been processed from the input data by the data compression circuitry using the compression system identified by the identification data.

In another example arrangement there is provided a method comprising:
decoding instructions for execution;
executing, using processing circuitry, instructions decoded by the instruction decoding step;
defining an interface for data communication with data compression circuitry;
in response to one or more instructions of an instruction set defined for the processing circuitry, the processing circuitry providing to the interface: input data to be processed by the data compression circuitry; and identification data identifying a compression system for use by the data compression circuitry to process the input data; and
the processing circuitry receiving from the interface: status data indicating whether data compression circuitry connected to the interface can process data using the compression system identified by the identification data; and, when the status data indicates that the data compression circuitry can process data using the compression system identified by the identification data, output data which has been processed from the input data by the data compression circuitry using the compression system identified by the identification data.

Further respective aspects and features of the disclosure are defined by the appended claims.

### BRIEF DESCRIPTION OF THE DRAWINGS

The present technique will be described further, by way of example only, with reference to embodiments thereof as illustrated in the accompanying drawings, in which:

FIG. 1 schematically illustrates a data processing apparatus;

FIG. 2 schematically illustrates an interface to a compression processor;

FIGS. 3 and 4 are schematic flowcharts illustrating respective methods; and

FIG. 5 schematically illustrates a simulator example

### DESCRIPTION OF EMBODIMENTS

### Overview of Processor

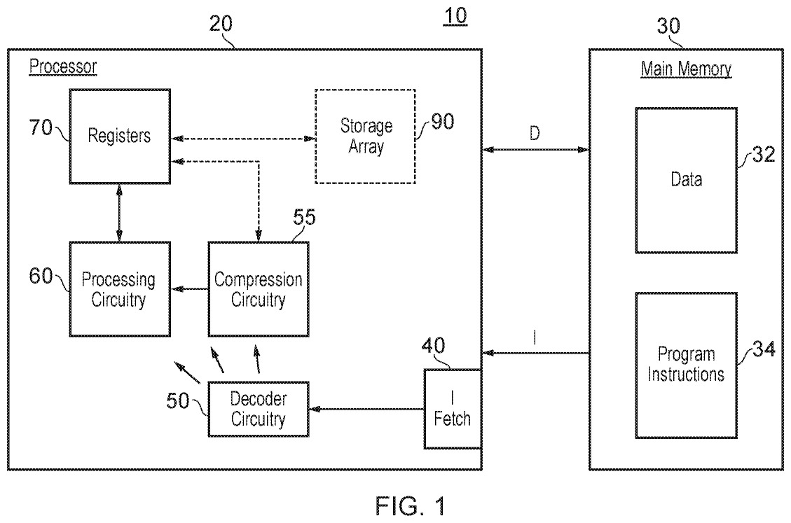

Referring now to the drawings, FIG. 1 schematically illustrates a data processing system 10 comprising a processor 20 coupled to a memory 30 storing data values 32 and program (or processing) instructions 34. The processor 20 includes an instruction fetch unit 40 for fetching program instructions 34 from the memory 30 and supplying the fetch program instructions to decoder circuitry 50. The decoder circuitry 50 decodes the fetched program instructions and generates control signals to control processing circuitry 60 to perform processing operations upon registers stored within register circuitry 70 as specified by the decoded vector instructions.

The processor 20 can optionally access a storage array 90. This is drawn in broken line to illustrate that it may or may not be provided as part of the processor 20. In example embodiments, the storage array 90 may store a square array portion of a larger or even higher-dimensioned array or matrix of data items in memory. The storage array may be considered in at least some examples as an accumulation array, referred to as “ZA” in a so-called Scalable Matrix Extension (SME) system provided or specified by Arm Limited.

In at least some examples, ZA is implemented as an n×m (square or rectangular) array of storage (or accumulation) elements. In some examples, n and m may be the same and may be equal to SVL or in other words the streaming vector length in use within the system (as defined with a so-called Scalable Vector Extension (SVE) or SVE2 system provided or specified by Arm Limited).

SME instructions can refer to various types of matrix operands, including “tiles” representing a subset of ZA. In some examples the tile is itself a square array but this is not a requirement and (for example) rectangular tiles could be used. So-called “tile vectors” represent rows or columns of ZA. An operand referred to as the “accumulator matrix” refers to the whole of ZA.

The processing circuitry 60 may provide or may include vector and/or matrix processing circuitry. A general distinction between scalar processing and vector processing is as follows. Vector processing involves applying a single vector processing instruction to data items of a data vector having a plurality of data items at respective positions in the data vector. Scalar processing operates on, effectively, single data items rather than on data vectors. Vector processing can be useful in instances where processing operations are carried out on many different instances of the data to be processed. In a vector processing arrangement, a single instruction can be applied to multiple data items (of a data vector) at the same time. This can improve the efficiency and throughput of data processing compared to scalar processing.

The processing circuitry can be used to perform operations with respect to matrices. Here, a matrix may be considered as an array of matrix elements. The array may be two dimensional or may have a higher dimensionality.

While the present embodiments may be relevant to vector and/or matrix processing, it is not a requirement that a vector or matrix processor is used.

The discussion below relates to example program instructions 34. Embodiments of the present disclosure include an apparatus, for example of the type shown in FIG. 1, operable or configured to decode and execute such program instructions.

The register circuitry 70 provides a set of physical registers, which can be allocated to architectural registers for the execution of the processing instructions. Architectural registers are defined by the processor architecture and its instruction set architecture (ISA). An instruction will define one or more architectural registers to hold source or destination (output) operands, but in actual execution these architectural registers will be implemented by respective physical registers 70. Where the registers are vector registers, these may be referred to as “Z” registers. In some examples, these may be scalable vector registers according to the prevailing vector length SVL in use, in accordance with the SVE or SVE2 systems mentioned above.

In performing such execution, the storage array may act as an accumulation array of the type discussed above as ZA. The processing circuitry, in response to a decoded instruction, may perform a processing operation such as a matrix processing operation using the storage array to accumulate the results of the operation. In other words, the instruction execution circuitry executes instructions decoded by the instruction decoder circuitry 50, the instruction execution circuitry being configured to execute a decoded instruction by reference to one or more source operands stored by the set of architectural registers and to hold one or more values generated by that decoded instruction. This could be an output for storage to an architectural register, or one or more values for storage to memory, or the like.

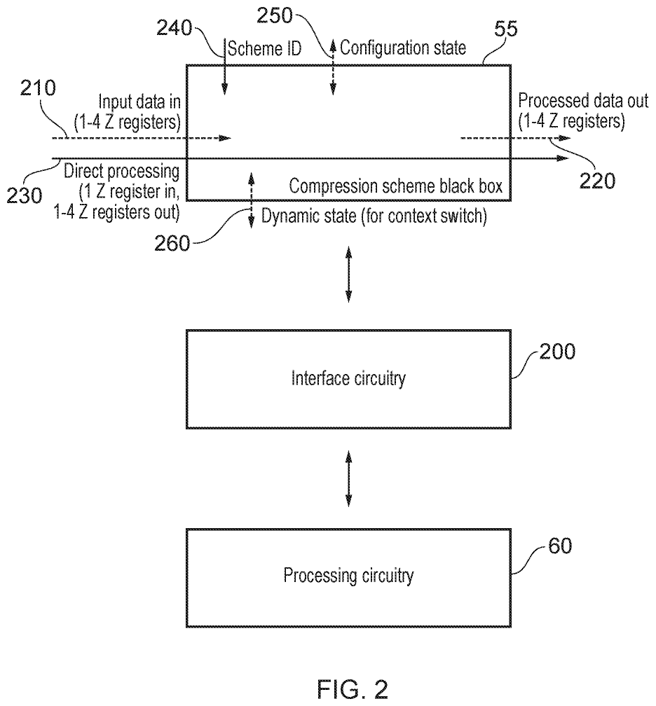

Compression circuitry 55 is provided which can provide a compression function as discussed below. In some examples the compression circuitry 55 can access at least a subset of the registers provided by the register circuitry 70. In general terms, interface circuitry between the compression circuitry 55 and the processing circuitry 60 may be provided; while this is not shown in FIG. 1 for clarity of that diagram, it will be discussed in connection with FIG. 2.

### Neural Processing and Weight Compression

In a particular example, in some situations the circuitry of FIG. 1 can be used for neural network processing. In this type of arrangement, data values to be processed are typically combined with (for example, multiplied by) a set of weight values. Such processing can involve performing many of these combinations and so can be performed conveniently by vector or matrix processors.

Weight compression can be a useful technique for neural networks. Compressing weights has the potential advantage of making overall models smaller and easier to distribute and also has the potential for higher performance as a lower bandwidth is required to load weight data into the processor for processing.

Two examples of this are lookup table based clustering and structured sparsity.

Examples of these techniques are discussed in Gong, Yunchao et al. “Compressing Deep Convolutional Networks using Vector Quantization.” ArXiv abs/1412.6115 (2014) (https://arxiv.org/pdf/1412.6115.pdf) and https://developer.nvidia.com/blog/accelerating-inference-with-sparsity-using-ampere-and-tensorrt/, the entire contents of both of these being incorporated by reference in the present application.

Clustering is a technique where processing values (typically weight or activation values) are coerced to one of a finite number of specific values. Each processing value can then be stored as an index into the codebook of values. Before such processing values can be used in a computation they need to be expanded back to the full sized representation.

Structured sparsity is a different technique where some of the processing values are forced to be zero. “Structured” means that the level of sparsity is enforced at a fine-grain level, for example so-called “2-in-4 sparsity” divides the processing values into blocks of 4, of which at least 2 must be zero. This allows the data to be represented as a half-sized array of the non-zero data values and some sideband “presence” data indicating where they lie within each block.

Both of these techniques are compelling due to the memory and bandwidth advantages—the sparse or clustered representation allows processing values to occupy less memory space and consume less bandwidth (or offer higher performance for a given fixed bandwidth) when they are used by an operation. Technical literature indicates this compression can be achieved with little or no impact on the functioning of the neural network (as measured by accuracy). It is also likely that these are far from the only techniques that can be used for this purpose. This presents a challenge for processors to convert the data to a more suitable form prior to computation, or else implement specialist operations to work directly on the compressed representation.

Example arrangements relate to the provision and interfacing of compression circuitry to handle such decompression, for example of processing values such as weight or activation values (though the techniques are independent of the nature of the actual data to be decompressed).

However, although processing value decompression is discussed as a worked example of the present techniques, the present examples are not limited to decompression. The compression circuitry could be used for data compression rather than decompression, for example by applying the 2-in-4 sparsity technique discussed in the present application. Indeed, at a basic level, the operation of the compression processor can be considered to provide a process to transform a data set from one representation to another. In general terms, “compression” is normally taken to imply that the destination format provides a representation using less data than the input format (whether losslessly or otherwise), whereas “decompression” is normally taken to imply that the destination format provides a representation using more data than the input format. The term “compression” as used here in connection with the data compression circuitry 55 or in connection with an algorithm, system, set of parameters or the like relating to operation of the compression circuitry 55 can encompass compression or decompression.

As mentioned above, a variety of compression schemes are in use, and this is an area of ongoing research, which implies that further compression schemes may be developed in the future. Given the value of compression but the lack of widespread standardization of the compression methodologies, example embodiments aim to provide a mechanism capable of supporting a variety of compression schemes.

One approach to supporting data compression or decompression could be to add extensions to the instruction set (as defined by the instruction set architecture or ISA applicable to the processing circuitry). This approach would require modifying the ISA in response to the development (or increased prevalence) of a compression technique. However, a process to modify the ISA of a processor can be relatively thorough and lengthy. Also, this could lead to obsolete techniques occupying the ISA encoding space, which is to say the set of values which can be used to represent instructions. This could be undesirable given that the ISA encoding space is finite and also that the presence of the obsolete techniques in the ISA could require a compatible processor to provide hardware to implement such obsolete techniques.

The techniques of the present disclosure can potentially provide one or more of: allowing a variety of compression schemes to be supported; allowing the inclusion of new schemes (and/or the deprecation of old ones) without necessarily requiring changes to operating systems or processing circuitry; and avoiding the need to consume further instruction set space for each additional compression scheme.

### Example of Compression Circuitry 55

FIG. 2 provides a schematic example showing the compression circuitry 55 (as an example of a data compression processor or circuitry), the processing circuitry 60 and interface circuitry 200 defining an interface for data communication between the processing circuitry 60 and the compression circuitry 55.

The compression circuitry 55 may be considered, for the purposes of this discussion, as a “compression scheme black box”, which is to say that from the point of view of the processing circuitry 60, in many respects it does not matter how the compression circuitry 55 operates; just that it is capable of receiving data and/or parameters in a certain format and outputting data in another certain format.

In some examples, the compression circuitry can receive clustered processing (for example weight or activation) values and/or weight values in a structured sparsity format and output decompressed processing values for use in neural processing by the processing circuitry 60.

The processing circuitry 60 is responsive to one or more instructions of an instruction set defined for the processing circuitry to provide to the interface:
input data to be processed by the data compression circuitry; and
identification data identifying a compression system for use by the data compression circuitry to process the input data. In other words, in these examples, the ISA provides for control of a generic ability of the processing circuitry to communicate with the compression circuitry 55 via the interface circuitry 200, but there is no need for the ISA to provide for specific control of a particular compression system or algorithm.

In particular, the data communication with the compression circuitry 55 may include a scheme ID (identifier) 240 which can define or identify a particular compression scheme to be used; a configuration state 250, for example defining parameters for use by the selected compression scheme such as a lookup table (LUT) for use in connection with the selected compression scheme; and optionally a dynamic state 260 to allow operation such as a context switch to occur (so that, for example, the dynamic state of the compression processor 55 can be retrieved and stored by the processing circuitry at a context switch and then reinstated when appropriate at a subsequent context switch). In other words, in connection with the dynamic state 260, the processing circuitry may be configured to receive state data defining a current operational state of the data compression circuitry from the interface; to execute a context switch comprising at least storing the state data; and to execute a further context switch comprising at least providing the stored state data back to the data compression circuitry.

The scheme ID and configuration state (and optionally the dynamic state) together allow for the definition of the compression scheme to be operated by the compression circuitry 55. In terms of data to be processed by the compression circuitry 55, this can be provided as input data to hundred 10 via a subset such as 1-4 of the Z registers accessible by the processing circuitry and by the compression circuitry 55, and processed data 220 can be output by the compression circuitry 55 again using a subset such as 1-4 of the Z registers.

The configuration state can be a bidirectional communication, so that the compression circuitry 55 can return data to the processing circuitry 60 via the interface circuitry 200 indicative of matters such as the compression circuitry 55's ability to perform the compression scheme defined by the scheme ID. So in these examples, the processing circuitry is configured to receive from the interface:
status data indicating whether data compression circuitry connected to the interface can process data using the compression system identified by the identification data (for example via the bidirectional communication of the configuration state); and
when the status data indicates that the data compression circuitry can process data using the compression system identified by the identification data, output data which has been processed from the input data by the data compression circuitry using the compression system identified by the identification data (for example as the processed data 220).

The interface circuitry 200 can provide data communication with the compression circuitry 55, for example making use of one or more of the registers implemented by the register circuitry 70, which registers may be accessible by the processing circuitry 60 and by the compression circuitry 55. In fact, all of the data communication functions of the interface circuitry 200 can be implemented by processor registers, or separate circuitry configured to receive data from each of the processing circuitry 60 and the compression circuitry 55 and to provide data to each of the processing circuitry 60 and the compression circuitry 55 can be used. In other words, in examples, the interface circuitry comprises one or more processor registers which are accessible by the processing circuitry and by data compression circuitry connected to the interface. For example, the processing circuitry may be configured to write at least the identification data to the one or more processor registers and to read at least the status data from the one or more processor registers.

The techniques defined here may apply to the processing circuitry and to the interface circuitry, with or without the compression circuitry 55 being present. In other words, the features of the present disclosure can be defined with respect to the arrangement of the processing circuitry and the interface circuitry.

As discussed above, the arrangement may comprise a data memory (for example, the memory 30 and/or the storage array 90); in which the processing circuitry is configured to execute instructions defining a neural network in which processing values are applied to data values; to read compressed data from the data memory defining the processing values; to provide the compressed data to the interface as input data and to receive, as output data, decompressed processing values for use by the instructions defining the neural network.

Similarly, the arrangement can be used to compress the processing values for use by other processors, for example in which the processing circuitry is configured to read data defining the processing values from the data memory; to provide the data defining the processing values to the interface as input data and to receive, as output data, compressed processing values.

### Direct Processing Path

A direct processing path 230 is also shown, comprising in this example 1 Z register as an input and 1-4 Z registers as an output. This provides a selectable pass-through path if required by the application in use.

In some examples at least two modes of operation are supported.

In one mode, loading input data and extracting output data are separate operations. This may be appropriate, for example, for structured sparsity where the “sideband” presence bits need to be provided but don't immediately produce output. It may also be useful for more advanced variable rate schemes where there is no fixed relationship between the input and output streams.

In another mode, so-called direct processing, the operations are combined so a single operation can provide input data and extract the corresponding output data. This may be useful for a lookup table scheme where there is a straightforward correspondence between the two—it reduces the number of instructions needed to perform the decompression and simplifies context switching (if separate input and output instructions are being used then the input data becomes part of the state in the meantime).

In practice a mixture could be used—for example structured sparsity could use the “input” mechanism to load the presence data, and then the “direct decompression” mode to expand an input vector to output vectors (implicitly consuming some of the presence data).

### Example Operations

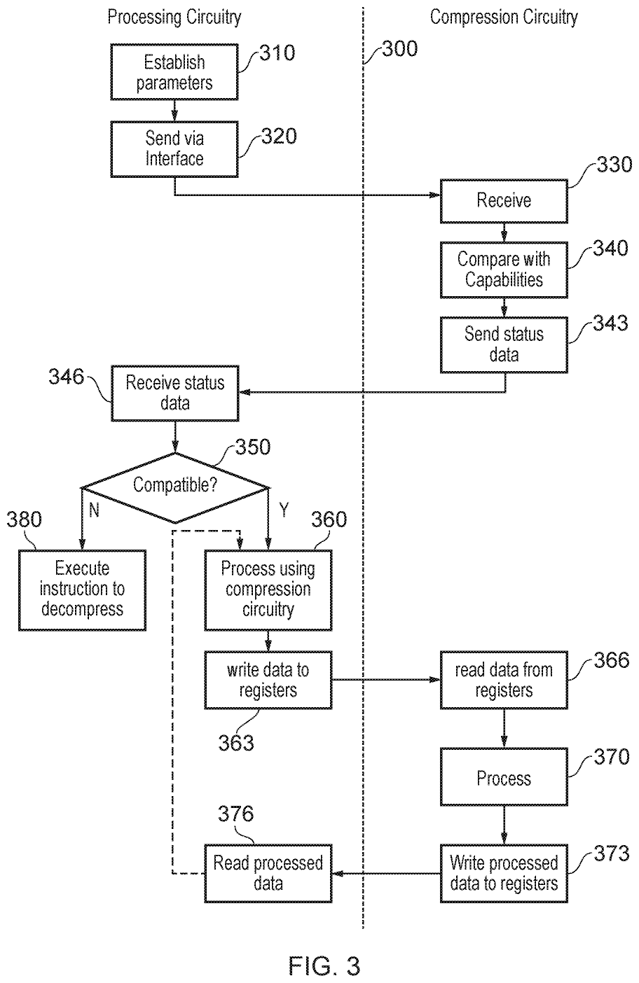

FIG. 3 is a schematic flowchart illustrating an example of operations as between the processing circuitry 60 (operations shown to the left of a vertical schematic boundary 300) and the compression circuitry 55 (operation shown to the right of the boundary 300).

At step 310, the processing circuitry establishes parameters for processing by the compression circuitry 55. As discussed above, this can be in response to execution of one or more instructions within the ISA of the processing circuitry 60, with the decoder circuitry 50 decoding the instructions for execution and the processing circuitry 60 executing those instructions as decoded by the decoder circuitry 50.

At a step 320 the processing circuitry provides at least the identification data to the compression circuitry 55 via the interface circuitry 200, and at a step 330, the compression circuitry receives at least the identification data.

At a step 340, the compression circuitry 55 compares the identification data, for example defining at least the scheme ID, with the processing capabilities of the compression circuitry 55 and returns a response to the processing circuitry 60 by sending status data at a step 343 and the processing circuitry receiving the status data at a step 346. This response may represent the status data discussed above.

At a step 350, the processing circuitry detects whether the status data indicates that the compression circuitry 55 is capable of handling the compression scheme defined by the scheme ID.

In terms of the negative outcome of the step 350, the processing circuitry is configured, when the status data indicates that the compression circuitry 55 cannot process data using the compression system identified by the identification data, to execute instructions to control the processing circuitry to perform processing of the input data.

If the outcome is yes then processing is performed so that the compression circuitry 55 processes and returns data. In particular, a step 360 represents the initiation of processing the data using the compression circuitry 55. At a step 363, depending on the interface technique in use, the processing circuitry 60 writes data to be processed to one or more registers and the compression circuitry 55 reads that data at a step 366. The compression circuitry 55 processes the data at a step 370. At a step 373 the compression circuitry writes the processed data to one or more registers and at a step 376 the processing circuitry reads the processed data. Control then optionally returns to the step 360 when there are more data to be processed in this way.

### Particular Example

A particular example will now be described.

The scheme ID (as an example of identification data) identifies the particular compression scheme in use. The scheme selected here controls how input data is transformed to output data and how the other framework features are used.

Within the overall system defined by the scheme ID, a scheme-specific state may be considered. This may define a configuration state; for example, as discussed above many compression schemes require a static state to be configured before processing can be take place. For example, a look-up table (LUT) based scheme requires the LUTs themselves to be set up. This may not be required by all schemes. If configuration data is only a few bits (e.g. an input/output width selector) it can be incorporated into the scheme ID.

With reference to the terminology used above, in these examples the identification data may be configured to define a compression algorithm and one or more parameters for use during execution of the compression algorithm. For example, the one or more parameters may comprise one or more look up tables for use with a compression algorithm defined by the identification data. In some examples the one or more parameters may comprise data defining an initial state to be applied to the data compression algorithm defined by the identification data.

The scheme-specific state may also define a dynamic state.

Most compression schemes will have dynamic state, such as compressed data that has been loaded in but not yet extracted or “internal” state such as dictionaries that are derived from the incoming data stream but need to be maintained to implement decompression.

Schemes which only support direct decompression might not require dynamic state.

The scheme-specific state may also define a combined state.

In order for the generic compression system to function, there should be a scheme-agnostic way to switch all the state associated with the scheme on context switch (and also potentially in user code, if a mechanism similar to ZA is used to manage it). This may include any configuration state. Also, software (that is to say, instructions for execution by the processing circuitry 60) making use of a particular scheme can use scheme-specific knowledge about how to configure and use it.

With regard to the reference above to a mechanism similar to ZA, the following further explanation is provided. In user code an ABI (application binary interface) mechanism may be provided which allows a calling function using ZA to call a second function (where the second function may or may not use any SME features), leaving a live state in ZA and storing a pointer to a save area for the ZA state. If at some point during processing of the second function (which might involve further function calls) ZA needs to be used, the called function checks the relevant status bit and, if necessary, stores the contents of ZA to the pointer before using ZA for whatever requirement is defined by the second function or a function called by the second function. When the second function returns, the calling function checks the status bit to see if the ZA contents have been saved, and if so restores them from the save area before resuming processing.

This potentially allows lower overhead if the second function does not use ZA (as the calling function does not have to save out ZA and later restore it when it actually has not changed), while not incurring too much overhead if it does, in that checks of the status bit would be needed on the entry to a function which uses ZA and on return from such a function call.

A similar scheme may be used for the state in the compression circuitry—such that the save code should be able to save the data out without knowing exactly what it is saving (which is similar to the context switch requirements).

In other words, in some examples, user functions might need to save/restore across function calls.

As discussed above, in terms of data input/output, all of the schemes make use of a mechanism (for example) to pass compressed (or input) data into the scheme and get decompressed (or processed) data out again. At least two variations are considered here.
Separate input/output instructions. Two distinct operations are provided: move from register to compressor (1-4 Z registers), and move from compressor to register (1-4 Z registers). This is well suited to schemes where there is not a simple, fixed ratio between input and output, or if multiple pieces of data are needed to effect processing (e.g. block or structured sparsity schemes).
Combined input/output instruction. This is a single instruction which consumes a single Z register and produces 1-4 Z registers of output.

In some examples, a register is dedicated or added to select a compression scheme. Bits 31:0 of this register identify the compression scheme to be used, with the reserved value of 0 indicating that no scheme is selected. If the value written to this register identifies a scheme that the current implementation does not support, the register is set to 0 by the compression circuitry 55. Software can read back the register to verify (as the status data) that the scheme is supported.

Further examples might enable the use of multiple compression schemes concurrently.

Compression schemes can have an associated state, either configured in advance before the scheme is used or populated during operation.

In some examples a system register is added or dedicated to indicate the amount of state currently stored (or, depending on scheme, can be set to configure the amount of state needed). It is scheme defined whether this register is read only or read write. Some schemes (e.g. lookup table) can function without reference to this register.

A further register may be dedicated or added to indicate the maximum possible live state size for any supported compression scheme. This can be used by operating systems to size fixed context switch buffers appropriately.

Two new instructions are added to read and write the state:
MOVCSSR0—Move to compression scheme state from register
The syntax may be: MOVCSSR0 Zt, Xn {, #<imm>, MUL VL}

This instruction would be to load state into the compression scheme. The compression scheme's state is modelled as a single 1D buffer of some length (as described in the preceding paragraph). Zt identifies a vector register holding the state to be loaded in, and Xn (possibly with “imm*VL” added on) indicating the offset in the buffer to be written to.
MOVRCSS0—Move from compression scheme state to register
The syntax may be: MOVROSS0 Zt, Xn {, #<imm>, MUL VL}

This is similar to above, but Xn identifies which bit of the buffer to copy and Zt indicates where to copy it to.

Three new instructions may be provided to actually do the compression, decompression or both.

### Load Compressed Data:

MOVCR0—Move to compression scheme from register
The syntax may be: MOVCR0 CRx, Zt {or multiple}

CRx is a compressed register ID, scheme specific meaning, maybe 3-4 bits.

The use of MOVRCSS0 and MOVCR0 as set out above provides an example of the provision by the ISA of separate respective instructions to provide identification data to the interface (MOVRCSS0 in this example) and to provide input data to the interface (MOVCR0 in this example).

### Extract Decompressed Data:

MOVRC0—Move to register from compression scheme
The syntax may be: MOVRC0 Zt {or multiple}, CRx

Zt defines a Z register. CRx is a register ID—a relationship between MOVCR and MOVRC is up to the compression scheme.

The use of the MOVRC0 instruction provides an example of the provision by the ISA of a further instruction to retrieve output data from the interface.

### Direct Decompression

DECOMP0—Decompress with scheme 0.
The syntax may be: DECOMP0 Zd {or multiple}, Zs, {sub ID}

Here, Zs is a source register and Zd is a destination register. The sub ID may be provided to select parts of the register if one Zs decompresses to more than one Zd.

This direct decompression instruction can provide an example of an instruction (defined by the ISA) to provide to the interface the input data and the identification data and to initiate processing of the input data by the data compression circuitry using a compression system defined by the identification data

An example relating to Lookup Tables will now be discussed. In this example, a scheme can be implemented which expands 2-bit or 4-bit compressed values to 8-, 16- or 32-bit values.

The input/output widths are encoded into the scheme ID, so there is a 1-bit field for 2 vs 4 bit encoded values, though in other examples this could leave space for 1- or 8-bit fields, and a 2-bit field encoding output width. The remaining 28-29 bits may have a constant value identifying this as the lookup table scheme. This provides an example in which in which the one or more parameters are configured to define respective input and output data widths for the compression scheme.

| | | Register to | |
|---|---|---|---|
| | | indicate amount | |
| Input width | Output width | of state | |
| 2-bit | 8-bit | 4 | bytes |
| 2-bit | 16-bit | 8 | bytes |
| 2-bit | 32-bit | 16 | bytes |
| 4-bit | 8-bit | 16 | bytes |
| 4-bit | 16-bit | 32 | bytes |
| 4-bit | 32-bit | 64 | bytes |

MOVCSSR0 is used to load in the lookup table state. Depending on VL and the state size (see table above), this might be possible with one operation or may require several.

Lookups are performed with DECOMP0. The lookup table, input and output width are all configured as described above, 1 input and 1-4 output registers are provided. In cases where the ratio is more than 4:1, the “sub ID” can be used to indicate which slice of the input to consume.

An example relating to structured sparsity will now be described.

This may for example support “2-in-4” structured sparsity for 8-, 16- or 32-bit datatypes. The nature of the sparsity scheme, for example defining a number (such as 2) of sparse blocks in a group of blocks (such as 4 blocks in an example “2-in-4” scheme) and/or the datatype in use are aspects which can separately or collectively be defined by parameters provided by or associated with the identification data.

The scheme ID could include a 2-bit width indicator as it affects the ratio of register accesses.

The register to indicate amount of state may indicate how much unused sparsity data remains in the sparsity data register—up to VL bytes.

In terms of the compression scheme state, nothing necessarily needs to be explicitly set up before using the scheme. Context switch code will read the register to indicate amount of state and use the state instructions to save/restore the sparsity data.

At decompression, it is assumed that sparsity data is stored separately. MOVCR0 is used to load the sparsity data. DECOMP0 is then used to convert one register of packed data into two registers of unpacked data, consuming an appropriate portion of sparsity data. The kernel is required to maintain the correct ratio between these two operations (i.e. 4:1 for 8-bit data, 8:1 for 16-bit data or 16:1 for 32-bit data).

In summary, example arrangements can offer the following features:
The full architectural detail can be defined in a separate specification for each scheme. Scheme development does not need to be aligned with the rest of the architectural process.
For implementations where the actual operations are handled by a remote unit, a host CPU can decode the architecturally specified operations and pass them on to the remote unit without needing to understand the details of the scheme in use. As such, schemes could be added to the remote unit without needing to touch the host CPU. This refers to some potential example arrangements implementing SME where there is a host processor and a separate SME unit which handles SME instructions. For non-SME code, the processor operates independently like any other. When SME code is encountered, the SME instructions are sent via a bus to the SME unit. The SME unit typically has its own memory input/output path and register bank. In the context of the present examples, where the “compression circuitry” is part of that SME unit, the host CPU does not necessarily need to know which compression schemes are supported or not. All accesses can be sent over to the SME unit for processing.
Unused schemes can be made obsolete independently of the actual architecture, although particular architecture releases could mandate support of certain schemes if desired.
There is no need to consume additional instruction set space with each additional scheme.

### Method Example

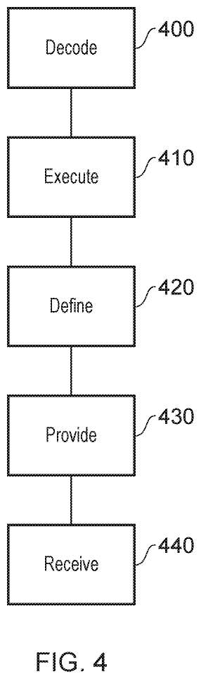

FIG. 4 is a schematic flowchart illustrating a method comprising:
decoding (at a step 400) instructions for execution;
executing (at a step 410), using processing circuitry, instructions decoded by the instruction decoding step;
defining (at a step 420) an interface for data communication with data compression circuitry;
in response to one or more instructions of an instruction set defined for the processing circuitry, the processing circuitry providing (at a step 430) to the interface: input data to be processed by the data compression circuitry; and identification data identifying a compression system for use by the data compression circuitry to process the input data; and
the processing circuitry receiving (at a step 440) from the interface: status data indicating whether data compression circuitry connected to the interface can process data using the compression system identified by the identification data; and, when the status data indicates that the data compression circuitry can process data using the compression system identified by the identification data, output data which has been processed from the input data by the data compression circuitry using the compression system identified by the identification data.

### Simulator Example

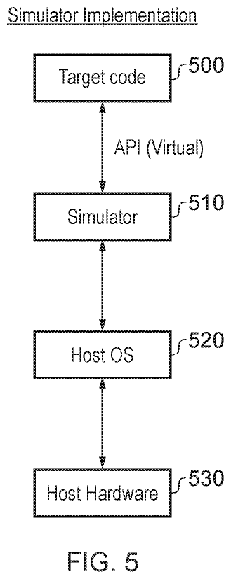

FIG. 5 illustrates a simulator implementation that may be used. Whilst the earlier described embodiments implement the present disclosure in terms of apparatus and methods for operating specific processing hardware supporting the techniques concerned, it is also possible to provide an instruction execution environment in accordance with the embodiments described herein which is implemented through the use of a computer program. Such computer programs are often referred to as simulators, insofar as they provide a software based implementation of a hardware architecture. Varieties of simulator computer programs include emulators, virtual machines, models, and binary translators, including dynamic binary translators. Typically, a simulator implementation may run on a host processor 530, optionally running a host operating system 520, supporting the simulator program 510. In some arrangements, there may be multiple layers of simulation between the hardware and the provided instruction execution environment, and/or multiple distinct instruction execution environments provided on the same host processor. Historically, powerful processors have been required to provide simulator implementations which execute at a reasonable speed, but such an approach may be justified in certain circumstances, such as when there is a desire to run code native to another processor for compatibility or re-use reasons. For example, the simulator implementation may provide an instruction execution environment with additional functionality which is not supported by the host processor hardware, or provide an instruction execution environment typically associated with a different hardware architecture. An overview of simulation is given in “Some Efficient Architecture Simulation Techniques”, Robert Bedichek, Winter 1990 USENIX Conference, Pages 53-63.

To the extent that embodiments have previously been described with reference to particular hardware constructs or features, in a simulated embodiment, equivalent functionality may be provided by suitable software constructs or features. For example, particular circuitry may be implemented in a simulated embodiment as computer program logic. Similarly, memory hardware, such as a register or cache, may be implemented in a simulated embodiment as a software data structure. In arrangements where one or more of the hardware elements referenced in the previously described embodiments are present on the host hardware (for example, host processor 530), some simulated embodiments may make use of the host hardware, where suitable.

The simulator program 510 may be stored on a computer-readable storage medium (which may be a non-transitory medium), and provides a program interface (instruction execution environment) to the target code 500 (which may include applications, operating systems and/or a hypervisor) which is the same as the application program interface of the hardware architecture being modelled by the simulator program 510. Thus, the program instructions of the target code 500, including code for implementing the functionality described above such as that described with reference to FIG. 4, may be executed from within the instruction execution environment using the simulator program 510, so that a host computer 530 which does not actually have the hardware features of the apparatus 10 discussed above can emulate these features.

### General Matters

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

Although illustrative embodiments of the present techniques have been described in detail herein with reference to the accompanying drawings, it is to be understood that the present techniques are not limited to those precise embodiments, and that various changes, additions and modifications can be effected therein by one skilled in the art without departing from the scope and spirit of the techniques as defined by the appended claims. For example, various combinations of the features of the dependent claims could be made with the features of the independent claims without departing from the scope of the present techniques.

1. Circuitry comprising:
instruction decoder circuitry to decode instructions for execution;
processing circuitry to execute instructions decoded by the instruction decoder circuitry;
interface circuitry defining an interface for data communication with data compression circuitry;
in which the processing circuitry is responsive to one or more instructions of an instruction set defined for the processing circuitry to provide to the interface: input data to be processed by the data compression circuitry; and identification data identifying a compression system for use by the data compression circuitry to process the input data; and
in which the processing circuitry is configured to receive from the interface: status data indicating whether data compression circuitry connected to the interface can process data using the compression system identified by the identification data; and, when the status data indicates that the data compression circuitry can process data using the compression system identified by the identification data, output data which has been processed from the input data by the data compression circuitry using the compression system identified by the identification data.

2. The circuitry of claim 1, in which the identification data is configured to define a compression algorithm and one or more parameters for use during execution of the compression algorithm.

3. The circuitry of claim 2, in which the one or more parameters comprise at least a portion of one or more look up tables for use with a compression algorithm defined by the identification data.

4. The circuitry of claim 3, in which the one or more parameters are configured to define respective input and output data widths for the compression scheme.

5. The circuitry of claim 2, in which the one or more parameters are configured to define one or more aspects of a structured sparsity compression algorithm, the one or more aspects comprising one or both of a number of sparse blocks in a group of blocks and a datatype in use by the algorithm.

6. The circuitry of claim 2, in which the one or more parameters comprise data defining an initial state to be applied to the data compression algorithm defined by the identification data.

7. The circuitry of claim 1, in which the instruction set defined for the processing circuitry comprises:
an instruction to provide to the interface the input data and the identification data and to initiate processing of the input data by the data compression circuitry using a compression system defined by the identification data.

8. The circuitry of claim 1, in which the instruction set defined for the processing circuitry comprises separate respective instructions to provide identification data to the interface and to provide input data to the interface.

9. The circuitry of claim 8, in which the instruction set defined for the processing circuitry comprises a further instruction to retrieve output data from the interface.

10. The circuitry of claim 1, in which the processing circuitry is configured to receive state data defining a current operational state of the data compression circuitry from the interface; to execute a context switch comprising at least storing the state data; and to execute a further context switch comprising at least providing the stored state data back to the data compression circuitry.

11. The circuitry of claim 1, in which the interface circuitry comprises one or more processor registers which are accessible by the processing circuitry and by data compression circuitry connected to the interface.

12. The circuitry of claim 11, in which the processing circuitry is configured to write at least the identification data to the one or more processor registers and to read at least the status data from the one or more processor registers.

13. The circuitry of claim 1, comprising a data memory; in which the processing circuitry is configured to execute instructions defining a neural network in which processing values are applied to data values; to read compressed data from the data memory defining the processing values; to provide the compressed data to the interface as input data and to receive, as output data, decompressed processing values for use by the instructions defining the neural network.

14. The circuitry of claim 1, in which the processing circuitry is configured to execute instructions defining a neural network in which processing values are applied to data values; to read data defining the processing values from the data memory; to provide the data defining the processing values to the interface as input data and to receive, as output data, compressed processing values.

15. The circuitry of claim 1, comprising: data compression circuitry connected to the interface.

16. The circuitry of claim 1, in which the processing circuitry is configured, when the status data indicates that the data compression circuitry cannot process data using the compression system identified by the identification data, to execute instructions to control the processing circuitry to perform processing of the input data.

17. A method comprising:
decoding instructions for execution;
executing, using processing circuitry, instructions decoded by the instruction decoding step;
defining an interface for data communication with data compression circuitry;
in response to one or more instructions of an instruction set defined for the processing circuitry, the processing circuitry providing to the interface: input data to be processed by the data compression circuitry; and identification data identifying a compression system for use by the data compression circuitry to process the input data; and
the processing circuitry receiving from the interface: status data indicating whether data compression circuitry connected to the interface can process data using the compression system identified by the identification data; and, when the status data indicates that the data compression circuitry can process data using the compression system identified by the identification data, output data which has been processed from the input data by the data compression circuitry using the compression system identified by the identification data.

18. A virtual machine computer program comprising instructions for controlling a host data processing apparatus to provide an instruction execution environment comprising:
instruction decoder circuitry to decode instructions for execution;
processing circuitry to execute instructions decoded by the instruction decoder circuitry;
interface circuitry defining an interface for data communication with data compression circuitry;
in which the processing circuitry is responsive to one or more instructions of an instruction set defined for the processing circuitry to provide to the interface: input data to be processed by the data compression circuitry; and identification data identifying a compression system for use by the data compression circuitry to process the input data; and
in which the processing circuitry is configured to receive from the interface: status data indicating whether data compression circuitry connected to the interface can process data using the compression system identified by the identification data; and, when the status data indicates that the data compression circuitry can process data using the compression system identified by the identification data, output data which has been processed from the input data by the data compression circuitry using the compression system identified by the identification data.
